(19) United States
(12) Patent Application Publication
(10) Pub. No.: US 2025/0126861 A1
(43) Pub. Date: Apr. 17, 2025

(54) SEMICONDUCTOR DEVICE

(71) Applicant: SAMSUNG ELECTRONICS CO., LTD., Suwon-si (KR)

(72) Inventors: Wooseok PARK, Suwon-si (KR); Donghoon HWANG, Suwon-si (KR); Myungil KANG, Suwon-si (KR); Wookhwan SONG, Suwon-si (KR); Doyoung CHOI, Suwon-si (KR)

(73) Assignee: SAMSUNG ELECTRONICS CO., LTD, Suwon-si (KR)

(21) Appl. No.: 18/745,312

(22) Filed: Jun. 17, 2024

(30) Foreign Application Priority Data
Oct. 13, 2023 (KR) 10-2023-0136950

(51) Int. Cl. H01L 29/08; H01L 29/06; H01L 29/423; H01L 29/775; H01L 29/786

(52) U.S. Cl. CPC H10D 62/151; H10D 30/43; H10D 30/6735; H10D 30/6757; H10D 62/121

(57) ABSTRACT

A semiconductor device includes: a substrate; an active region extending in a first direction on the substrate; a gate structure extending in a second direction on the active region and intersecting the active region; a source/drain region on the active region on a side of the gate structure; a separation pattern extending in the first direction and separating the gate structure; and a contact structure on the separation pattern and crossing the separation pattern, the contact structure being electrically connected to the source/drain region, wherein the contact structure includes a first portion and a second portion, the first portion contacts the separation pattern, the second portion contacts the source/drain region, a lower surface of the second portion is at a level lower than a lower surface of the first portion, and a lowermost end of the contact structure is spaced apart from the separation pattern.

### CROSS-REFERENCE TO RELATED APPLICATION

This application is based on and claims priority under 35 U.S.C. § 119 to Korean Patent Application No. 10-2023-0136950, filed on Oct. 13, 2023 in the Korean Intellectual Property Office, the disclosure of which is incorporated by reference herein in its entirety.

### BACKGROUND

### 1. Field

The disclosure relates to a semiconductor device.

### 2. Description of Related Art

As demands for high performance, high speed, and/or multi-functionality of semiconductor devices increase, a degree of integration of semiconductor devices is increasing. In manufacturing fine-patterned semiconductor devices in response to the trend for high integration of semiconductor devices, it is necessary to implement patterns with a fine width or a fine separation distance. In addition, in order to overcome limitations in operating characteristics due to size reductions of a planar metal oxide semiconductor field-effect transistor (MOSFET), efforts are being conducted to develop semiconductor devices including fin-shaped field-effect transistor (FinFET) with a three-dimensional channel.

### SUMMARY

Provided is a semiconductor device which may have an improved degree of integration and reliability.

According to an aspect of an example embodiment, a semiconductor device includes: a substrate; an active region extending in a first direction on the substrate; a gate structure extending in a second direction on the active region and intersecting the active region; a source/drain region on the active region on a side of the gate structure; a separation pattern extending in the first direction and separating the gate structure; and a contact structure on the separation pattern and crossing the separation pattern, the contact structure being electrically connected to the source/drain region, wherein the contact structure includes a first portion and a second portion, the first portion contacts the separation pattern, the second portion contacts the source/drain region, a lower surface of the second portion is at a level lower than a lower surface of the first portion, and a lowermost end of the contact structure is spaced apart from the separation pattern.

According to an aspect of an example embodiment, a semiconductor device includes: a substrate; an active region extending in a first direction on the substrate; a gate structure extending in a second direction on the active region and intersecting the active region; a source/drain region on the active region on at least one side of the gate structure; and a contact structure electrically connected to the source/drain region, wherein a lower surface of the contact structure includes a first surface, a second surface at a level lower than the first surface, and an inner side surface connecting the first surface and the second surface, the first surface is spaced apart from the source/drain region, the second surface contacts the source/drain region, and the inner side surface is inclined so that a width of the contact structure becomes narrower toward the substrate.

According to an aspect of an example embodiment, a semiconductor device includes: a substrate; a plurality of active regions extending in a first direction on the substrate, and spaced apart from each other in a second direction intersecting the first direction; a plurality of gate structures extending in the second direction on the plurality of active regions; a plurality of source/drain regions on at least one side of the plurality of gate structures on the plurality of active regions; a separation pattern extending in the first direction between the plurality of source/drain regions, and penetrating at least one gate structure among the plurality of gate structures to separate the at least one gate structure; and a contact structure contacting the separation pattern on the separation pattern, and contacting a first source/drain region and a second source/drain region among the plurality of source/drain regions, wherein a first lower surface of the contact structure contacting the separation pattern is at a level higher than a second lower surface of the contact structure contacting the first source/drain region and the second source/drain region, at least a portion of an inner side surface of the contact structure connecting the first lower surface and the second lower surface is spaced apart from the separation pattern, and the first source/drain region and the second source/drain region include impurities having different conductivity types.

### BRIEF DESCRIPTION OF THE DRAWINGS

The above and other aspects, features, and advantages of the disclosure will be more clearly understood from the following detailed description, taken in conjunction with the accompanying drawings, in which:

FIG. 1 is a plan view illustrating a semiconductor device according to example embodiments;

FIGS. 2A to 2D are cross-sectional views illustrating a semiconductor device according to example embodiments;

FIGS. 3A to 3B are cross-sectional views illustrating a semiconductor device according to example embodiments;

FIG. 4 is a cross-sectional view illustrating a semiconductor device according to example embodiments;

FIG. 5 is a cross-sectional view illustrating a semiconductor device according to example embodiments;

FIG. 6 is a cross-sectional view illustrating a semiconductor device according to example embodiments;

FIG. 7 is a plan view illustrating a semiconductor device according to example embodiments;

FIGS. 8 to 10 are cross-sectional views illustrating a semiconductor device according to example embodiments; and

FIGS. 11 to 19 are diagrams illustrating a process sequence to explain a method of manufacturing a semiconductor device according to example embodiments.

### DETAILED DESCRIPTION

Hereinafter, example embodiments of the disclosure will be described with reference to the accompanying drawings. Hereinafter, terms such as ‘upper,’ ‘upper portion,’ ‘upper surface,’ ‘lower,’ ‘lower portion,’ ‘lower surface,’ ‘side surface,’ and the like, may be understood as referring to the drawings, unless otherwise indicated by reference numerals.

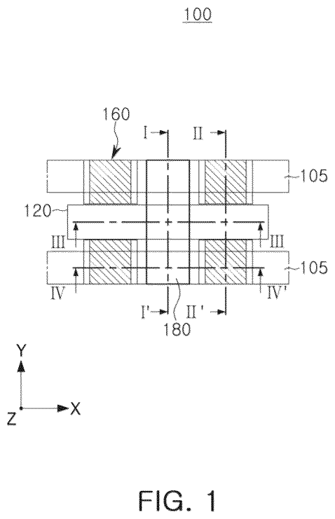

FIG. 1 is a plan view illustrating a semiconductor device according to example embodiments. For convenience of description, only some components of the semiconductor device are illustrated in FIG. 1.

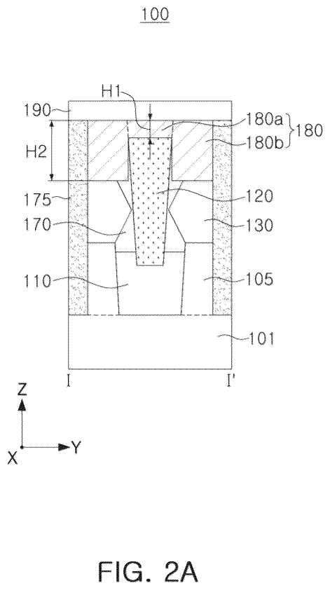

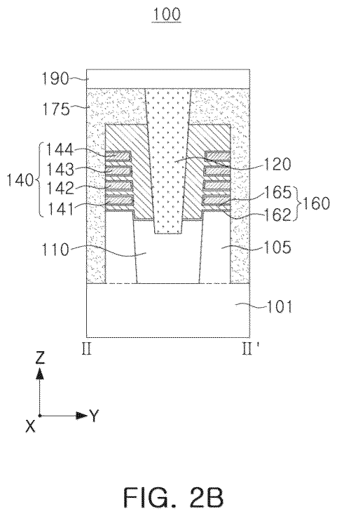

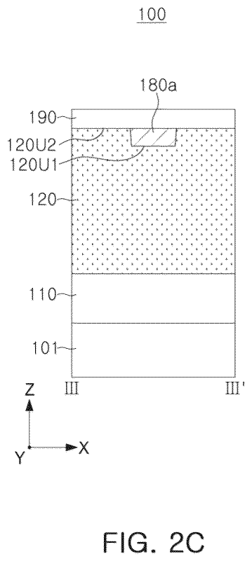

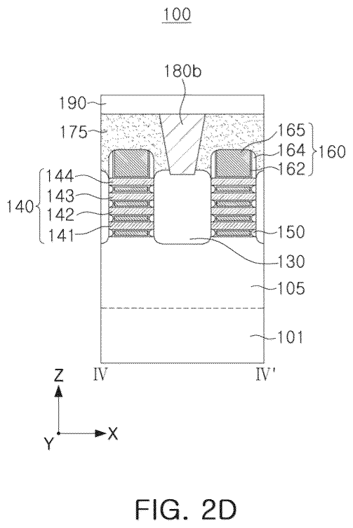

FIGS. 2A to 2D are cross-sectional views illustrating a semiconductor device according to example embodiments. FIG. 2B illustrates a cross-section of the semiconductor device of FIG. 1 taken along line II-II′. FIG. 2C illustrates a cross-section of the semiconductor device of FIG. 1 taken along line III-III′. FIG. 2D illustrates a cross-section of the semiconductor device of FIG. 1 cut taken along line IV-IV′.

Referring to FIGS. 1 to 2D, a semiconductor device 100 may include a substrate 101 including an active region 105, channel structures 140 including first to fourth channel layers 141, 142, 143, and 144 disposed to be spaced apart from each other vertically on the active region 105, a gate structure 160 extending across the active region 105 and respectively including a gate electrode 165, a separation pattern 120 separating the gate structure 160, a source/drain region 130 in contact with the channel layers 140, and a contact structure 180 connected to the source/drain region 130. The semiconductor device 100 may further include a device isolation layer 110, an interlayer insulating layer 170, an insulating region 175, and an upper insulating layer 190.

In the semiconductor device 100, the active region 105 may have a fin structure, and the gate electrode 165 may be disposed between the active region 105 and the channel structure 140, between the first to fourth channel layers 141, 142, 143, and 144 of the channel structure 140, and on the channel structure 140. Accordingly, the semiconductor device 100 may include transistors of a structure of Multi-Bridge-Channel FET (MBCFET™), a gate-all-around type field effect transistor.

The substrate 101 may have an upper surface extending in X- and Y-directions. The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a Silicon-On-Insulator (SOI) layer, or a Semiconductor-On-Insulator (SeOI) layer.

The substrate 101 may include an active region 105 disposed in, on, or above the substrate 101. The active region 105 may be surrounded by the device isolation layer 110 within the substrate 101, and may be disposed to extend in a first direction, for example, an X-direction. However, depending on an explanation method of this disclosure, it may be described that the active region 105 is configured separately from the substrate 101. A portion of the active region 105 may protrude onto the device isolation layer 110, and an upper surface of the active region 105 may be located on a level higher than that of the device isolation layer 110. Throughout the disclosure, the ‘level’ corresponds to a position in Z-direction (a third direction).

The active region 105 may be formed of a part of the substrate 101 or may include an epitaxial layer grown from the substrate 101. However, on one side of the gate structure 160, the active region 105 may be partially recessed to form a recess region, and source/drain regions 130 may be disposed in the recess region.

In example embodiments, the active region 105 may or may not include a well region containing impurities. For example, in the case of a P-type transistor (pFET), the well region may include N-type impurities such as phosphorus (P), arsenic (As), or antimony (Sb). In the case of an N-type transistor (nFET), the well region may include P-type impurities such as boron (B), gallium (Ga), or indium (In). The well region may be located at a predetermined depth, for example, from an upper surface of the active region 105.

The device isolation layer 110 may define an active region 105 in the substrate 101. The device isolation layer 110 may surround an active region 105 in the substrate 101. The device isolation layer 110 may be formed by, for example, a shallow trench isolation (STI) process. The device isolation layer 110 may expose the upper surface of the active region 105 and may partially expose the upper portion. In some example embodiments, the device isolation layer 110 may have a curved upper surface to have a higher level as it is more adjacent to the active region 105. The device isolation layer 110 may be formed of an insulating material. The device isolation layer 110 may be, for example, an oxide, a nitride, or a combination of an oxide and a nitride.

The separation pattern 120 may be disposed to be adjacent to the active region 105 to extend in a first direction in which the active region 105 extends, for example, an X-direction. The separation pattern 120 may be disposed to extend in a direction intersecting the gate structure 160, for example, in the X-direction. The separation pattern 120 may be disposed to be spaced apart from the active region 105, the source/drain region 130, and the substrate 101. The separation pattern 120 may be disposed to contact the gate structure 160, and the gate structure 160 may be separated by the separation pattern 120. Referring to FIG. 2C, an upper surface of the separation pattern 120 may include a first upper surface 120U1 in contact with a lower surface of the first portion 180a and a second upper surface 120U2 located on a level higher than the first upper surface 120U1. The first upper surface 120U1 and the second upper surface 120U2 may be located on a level higher than an upper end of the source/drain region 130 and an upper end of the gate electrode 165. The first upper surface 120U1 of the separation pattern 120 may be located on a level lower than an upper surface of the insulating region 175. The second upper surface 120U2 of the separation pattern 120 may be coplanar with the upper surface of the first portion 180a of the contact structure 180, and may be in contact with a lower surface of the upper insulating layer 190. A surface connecting the first upper surface 120U1 and the second upper surface 120U2 may contact a side surface of the first portion 180a of the contact structure 180. A lower surface of the separation pattern 120 may be located on a level lower than a lower end of the source/drain region 130, and the lower surface of the separation pattern 120 may be located on a level lower than an interface between the device isolation layer 110 and the interlayer insulating layer 170. That is, the separation pattern 120 may penetrate through the interlayer insulating layer 170 and extend into an interior of the device isolation layer 110. A width of the separation pattern 120 may decrease toward the substrate 101. In a cross-section of the separation pattern 120 in the first direction (see FIG. 2C), the separation pattern 120 may have a shape surrounding the lower surface and the side surface of the first portion 180a of the contact structure 180. In an example embodiment, a side surface of the separation pattern 120 may be disposed perpendicular to the upper surface of the substrate 101, so that the width of the separation pattern 120 may be constant. The separation pattern 120 may include an insulating material, for example, a silicon nitride, a silicon oxynitride, or a combination of the silicon nitride, the silicon oxynitride. The separation pattern 120 may have a material composition different from that of the interlayer insulating layer 170, and may include a material having etch selectivity different from that of the interlayer insulating layer 170.

The gate structure 160 may intersect the active region 105 and the channel structures 140 on the active region 105 and the channel structures 140, and may be disposed to extend in a second direction, for example, in a Y-direction. The gate structure 160 may be separated by a separation pattern 120, and in a cross-sectional view in the second direction (see FIG. 2B), one side of the gate structure 160 may be in contact with the separation pattern 120, and the other side opposite of the gate structure 160 may be in contact with the insulating region 175.

Functional channel regions of transistors may be formed in the active region 105 and/or the channel structures 140 intersecting the gate electrode 165 of the gate structure 160. The gate structure 160 may include a gate electrode 165, a gate dielectric layer 162 between the gate electrode 165 and the first to fourth channel layers 141, 142, 143, and 144, and gate spacer layers 164 on a side surface of the gate electrode 165. In an example embodiment, the gate structure 160 may further include a capping layer on an upper surface of the gate electrode 165. Alternatively, a portion of the insulating region 175 on the gate structure 160 may be referred to as a gate capping layer.

The gate dielectric layer 162 may be disposed between the active region 105 and the gate electrode 165 and the channel structure 140 and the gate electrode 165, and may be disposed to cover at least a portion of the surfaces of the gate electrode 165. For example, the gate dielectric layer 162 may be disposed to surround all surfaces except the top surface of the gate electrode 165, a surface on which the gate electrode 165 is in contact with the separation pattern 120, and a surface in contact with the insulating region 175. The gate dielectric layers 162 may extend between the gate electrode 165 and the gate spacer layers 164, but embodiments of the disclosure are not limited thereto. The gate dielectric layers 162 may include an oxide, a nitride, or a high-K material. The high-K material may mean a dielectric material having a higher dielectric constant than silicon oxide (SiO₂). The high dielectric constant material may be any one of, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓOₓ), hafnium oxide (HfO₂), hafnium silicon oxide (HfSiₓO_{y}), lanthanum oxide (La₂O₃), lanthanum aluminum oxide (LaAlO_{y}), lanthanum hafnium oxide (LaHfRO_{y}), hafnium aluminum oxide (HfAlₓO_{y}), and praseodymium oxide (Pr₂O₃). Depending on example embodiments, the gate dielectric layer 162 may be formed of a multilayer film.

The gate electrode 165 may be disposed to fill a gap between the first to fourth channel layers 141, 142, 143, and 144 on the active region 105 and extend onto the channel structure 140. The gate electrode 165 may be spaced apart from the first to fourth channel layers 141, 142, 143, and 144 by the gate dielectric layers 162. The gate electrode 165 may include a conductive material, and for example, a metal nitride such as titanium nitride (TiN), tantalum nitride (TaN), or tungsten nitride (WN), and/or a metal material such as aluminum (Al), tungsten (W), or molybdenum (Mo), or a semiconductor material such as doped polysilicon. Depending on embodiments, the gate electrode 165 may be composed of two or more multilayer structures.

The gate spacer layers 164 may be disposed on the channel structure 140 on both side surfaces of the gate electrode 165. The gate spacer layers 164 may insulate the source/drain regions 130 and the gate electrode 165. The gate spacer layers 164 may have a multilayer structure according to example embodiments. The gate spacer layers 164 may be formed of at least one of oxide, nitride, oxynitride, and may be formed of, for example, a low-dielectric constant film.

The channel structures 140 may be disposed on the active region 105 in regions where the active region 105 intersects the gate structure 160. Each of the channel structures 140 may include first to fourth channel layers 141, 142, 143, and 144, a plurality of channel layers disposed to be spaced apart from each other in the Z-direction. The first to fourth channel layers 141, 142, 143, and 144 may be sequentially disposed from the bottom, and the first channel layer 144 may be the top channel layer. One side of the first to fourth channel layers 141, 142, 143, and 144 may be etched by the insulating region 175, and may be in contact with the insulating region 175. The channel structures 140 may be connected to source/drain regions 130. The channel structures 140 may have the same or similar width as the gate structures 160 in the X-direction, and may have the same or a smaller width than the active region 105 in the Y-direction. In a cross section in the y direction, a channel layer disposed below the first to fourth channel layers 141, 142, 143, and 144 may have a width equal to or greater than that of another channel layer disposed above the first to fourth channel layers 141, 142, 143, and 144. The number and shape of channel layers forming one channel structure 140 may vary in various embodiments. For example, one channel structure 140 may include three channel layers, two channel layers, or five or more channel layers.

The channel structures 140 may be formed of a semiconductor material, and may include, for example, at least one of silicon (Si), silicon germanium (SiGe), and germanium (Ge). For example, the channel structures 140 may be formed of the same material as the active region 105. In some example embodiments, the channel structures 140 may include an impurity region located adjacent to the source/drain regions 130. Each of the channel layers 141, 142, 143, and 144 of the channel structures 140 may include a semiconductor material and have a shape of nano sheets having a thickness in a Z-direction of several nanometers.

The source/drain region 130 may be disposed in a recess region in which an upper portion of the active region 105 is partially recessed on one side or both sides of the gate structure 160. The recess region may extend along side surfaces of the channel structures 140 and side surfaces of the gate dielectric layers 162. The source/drain region 130 may be disposed to cover side surfaces of each of the first to fourth channel layers 141, 142, 143, and 144 of the channel structure 140 in the X-direction. The upper surface of the source/drain region 130 may be located at the same level or higher than the lower surface of the gate electrode 165 on the channel structures 140, and the level may be variously changed in various example embodiments. In an example embodiment, a side surface of the source/drain region 130 may be curved according to the first to fourth channel layers 141, 142, 143, and 144 and the gate structure 160. However, a specific shape of the side surfaces of the source/drain regions 130 may be variously changed in various example embodiments.

The source/drain region 130 may include a semiconductor material, for example, at least one of silicon (Si) and germanium (Ge), and may further include dopants. For example, when the semiconductor device 100 is a pFET, the dopants may be at least one of boron (B), gallium (Ga), and indium (In). The source/drain region 130 may be formed of an epitaxial layer.

The internal spacer layers 150 may be disposed to be parallel to the gate electrode 165 between the first to fourth channel layers 141, 142, 143, and 144 in the Z-direction. The gate electrode 165 may be stably spaced apart from the source/drain regions 130 by the internal spacer layers 150 and may be electrically separated. The internal spacer layers 150 may have a shape in which side surfaces of the internal spacer layers 150 facing the gate electrode 165 are convexly rounded inwardly toward the gate electrode 165, but embodiments of the disclosure are not limited thereto. The internal spacer layers 150 may include at least one of oxide, nitride, and oxynitride, and may be made of, for example, a low dielectric constant film. However, in some example embodiments, the internal spacer layers 150 may be omitted.

The contact structure 180 may be disposed on the separation pattern 120 to extend in a second direction, for example, the Y-direction, across the separation pattern. The contact structure 180 may penetrate the interlayer insulating layer 170 and be connected to the source/drain region 130, and may apply an electrical signal to the source/drain region 130. The contact structure 180 may be disposed to recess a portion of the source/drain region 130.

The contact structure 180 may include a first portion 180a including a lower surface in contact with the separation pattern 120 and a second portion 180b including a lower surface in contact with the source/drain region 130. A lower surface of the first portion 180a may be referred to as a first surface, and a lower surface of the second portion 180b may be referred to as a second surface. An area of the second surface may be larger than an area of the first surface. The first portion 180a may be located between the second portions 180b in the second direction. The lower surface of the second portion 180b may be located on a level lower than the lower surface of the first portion 180a. The lower surface of the first portion 180a may be located on a level higher than the upper end of the source/drain region 130. An upper surface of the first portion 180a and an upper surface of the second portion 180b may be coplanar, and a thickness H1 of the first portion 180a may be smaller than a thickness H2 of the second portion 180b. A portion of the second portion 180b may overlap a portion of the separation pattern 120 in the second direction (e.g., Y-direction).

A lower surface of the contact structure 180 may include an inner side surface connecting the first surface, which is the lower surface of the first portion 180a, and the second surface, which is the lower surface of the second portion 180b. At least a portion of the inner side surface may be spaced apart from the separation pattern 120, and the inner side surface may be inclined so that a width of the contact structure 180 becomes narrower toward the substrate. The lowermost end of the contact structure 180 may be included in the second surface, and may be spaced apart from the separation pattern 120. A space between the second portion 180b located on a level lower than the lower surface of the first portion 180a and the separation pattern 120 may be disposed to be filled by the interlayer insulating layer 170. In an example embodiment, the inner side surface may be perpendicular to the upper surface of the substrate 101. In an example embodiment, at least a portion of the inner side surface may be in contact with the separation pattern 120, or an entire inner side surface of the inner side surface may be in contact with the separation pattern 120.

Among the gate structures 160 disposed adjacently in the y direction with the separation pattern 120 interposed therebetween, a transistor formed by one gate structure 160 may be a PMOS, and a transistor formed by the other gate structure 160 may be an NMOS. Accordingly, the contact structure 180 may connect the source/drain region 130 of the PMOS and the source/drain region 130 of the NMOS. Depending on the embodiment, both sides of the gate structures 160 separated by the separation pattern 120 and disposed adjacently to the separation pattern 120 in the y direction may be the same PMOS transistor or NMOS transistor.

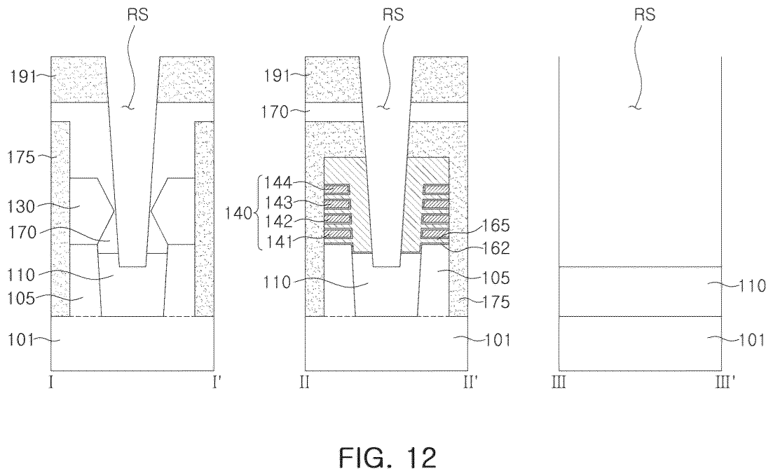

Such a semiconductor device 100 may have a structure in which the gate structure 160 is separated by forming a line-shaped recess region RS (see FIG. 12) crossing the gate structure 160, the separation pattern 120 fills a portion of the recess region RS, and the first portion 180a of the contact structure 180 fills a portion of the recess region RS on the separation pattern 120. Accordingly, the gate separation may be performed in a line form, thereby stably separating the gate structure 160 and forming the contact structure 180 by a self-aligned contact (SAC) process. By including the separation pattern 120 and the contact structure 180 of this form, a semiconductor device with improved integration and reliability can be provided.

The interlayer insulating layer 170 may be disposed to cover upper surfaces of the source/drain region 130 and the device isolation layer 110. The interlayer insulating layer 170 may include at least one of oxide, nitride, and oxynitride, and for example, a low-dielectric constant material. According to example embodiments, the interlayer insulating layer 170 may include a plurality of insulating layers. The interlayer insulating layer 170 may include a material having etch selectivity different from that of the separation pattern 120.

The insulating region 175 may be disposed to cover a portion of the substrate 101 and the active region 105. The insulating region 175 may cover the remaining portion of the device isolation layer 110 not covering the substrate 101 and the active region 105. The insulating region 175 may cover at least a portion of the remaining portion of the active region 105, the source/drain region 130, and the contact structure 180, not covered by the interlayer insulating layer 170. The insulating region 175 may cover at least a portion of the source/drain region 130, not covered by the interlayer insulating layer 170. A side surface of the active region 105, adjacent to the separation pattern 120, may be in contact with the device isolation layer 110 and the interlayer insulating layer 170, and a side surface of the active region 105 on a side opposite to the separation pattern 120 may be in contact with an insulating region 175. That is, the insulating region 175 may cover one side surface of the contact structure 180, the source/drain region 130, and the active region 105. The insulating region 175 may be disposed to be spaced apart from the separation pattern 120, and may be disposed to contact the contact structure 180. The insulating region 175 may cover an upper surface and a side surface of the gate electrode 165, and a portion of the insulating region 175 covering the upper surface of the gate structure 160 may be referred to as a gate capping layer. A side surface of the insulating region 175 may be perpendicular to the upper surface of the substrate 101, but embodiments of the disclosure are not limited thereto. For example, the insulating region 175 may have a side surface inclined so that a width of the insulating region 175 decreases toward the substrate 101, and conversely, the insulating region 175 may have a side surface inclined so that a width of the insulating region 175 increases toward the substrate 101. A lower surface of the insulating region 175 may be located on substantially the same level as the lower surface of the device isolation layer 110, but embodiments of the disclosure are not limited thereto. For example, the lower surface of the insulating region 175 may be located on a level higher than the upper surface of the substrate 101, and a space between the lower surface of the insulating region 175 and the substrate 101 may be filled with the device isolation layer 110. In an example embodiment, the insulating region 175 may have a shape extending into the interior of the substrate 101. The insulating region 175 may include at least one of oxide, nitride, and oxynitride, and may include, for example, a low-dielectric constant material.

The upper insulating layer 190 may be disposed to cover an upper surface of the contact structure 180 and an upper surface of the insulating region 175. The upper insulating layer 190 may include at least one of oxide, nitride, and oxynitride, for example, a low-dielectric constant material. According to example embodiments, the upper insulating layer 190 may include a plurality of insulating layers.

In the description of the following example embodiments, overlapping descriptions with those described above with reference to FIGS. 1 to 2D will be omitted.

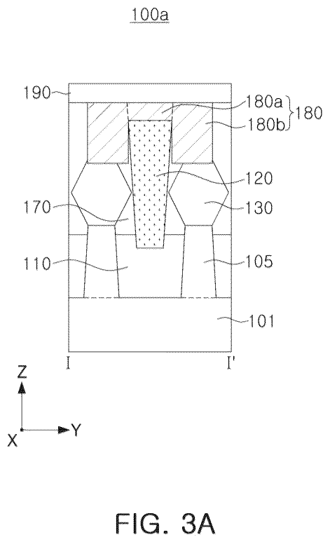

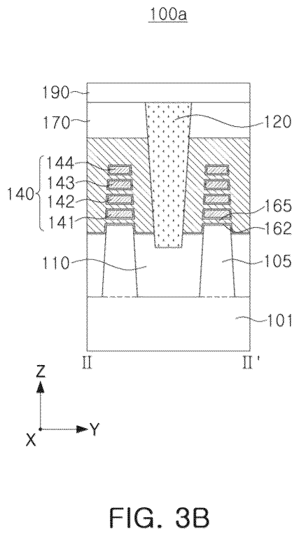

FIGS. 3A and 3B are cross-sectional views illustrating a semiconductor device according to example embodiments. FIG. 3A illustrates a cross-section corresponding to a cross-section cut taken along line I-I′ of FIG. 1, and FIG. 3b illustrates a cross-section corresponding to a cross-section cut taken along line II-II′ of FIG. 1.

Referring to FIGS. 3A and 3B, in a semiconductor device 100a, the device isolation layer 110 may cover a side surface adjacent to a separation pattern 120 of the active region 105 and a side surface opposite to the separation pattern 120. The interlayer insulating layer 170 may cover at least a portion of the active region 105, the source/drain region 130, and the contact structure on the device isolation layer 110, and the interlayer insulating layer 170 may cover an upper surface of the gate electrode 165. A portion of the interlayer insulating layer 170 covering the upper surface of the gate electrode 165 may be referred to as a gate capping layer.

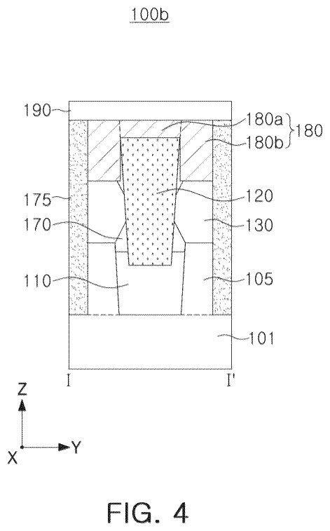

FIG. 4 is a cross-sectional view illustrating a semiconductor device according to example embodiments. FIG. 4 illustrates a cross-section corresponding to the cross-section cut taken along line I-I′ in FIG. 1.

Referring to FIG. 4, the separation pattern 120 of the semiconductor device 100b may be disposed to contact the source/drain region 130. The separation pattern 120 may be disposed to recess a portion of the source/drain region 130. Even in this case, the separation pattern 120 may be disposed to be spaced apart from the active region 105 and the substrate 101.

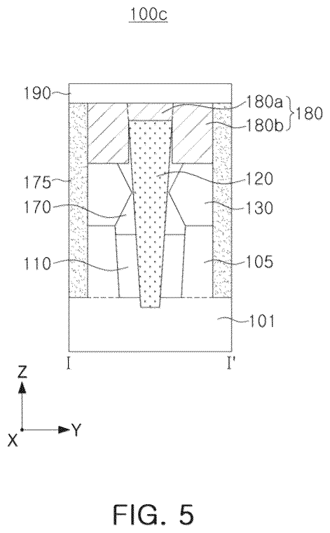

FIG. 5 is a cross-sectional view illustrating a semiconductor device according to example embodiments. FIG. 5 illustrates a cross-sectional view corresponding to the cross-section cut taken along line I-I′ in FIG. 1.

Referring to FIG. 5, the separation pattern 120 of the semiconductor device 100c may extend in the third direction, perpendicular to (the second direction of) an upper surface of the substrate 101, for example, the Z-direction, to extend into the interior (internal area) area of the substrate 101, and may penetrate the device isolation layer 110. Accordingly, the separation pattern 120 may be in contact with the contact structure 180, the interlayer insulating layer 170, the device isolation layer 110, and the substrate 101 at the same time. As illustrated in FIG. 5, the separation pattern 120 may be spaced apart from the source/drain region 130, but embodiments of the disclosure are not limited thereto. In an example embodiment, the separation pattern 120 may also contact the source/drain region 130.

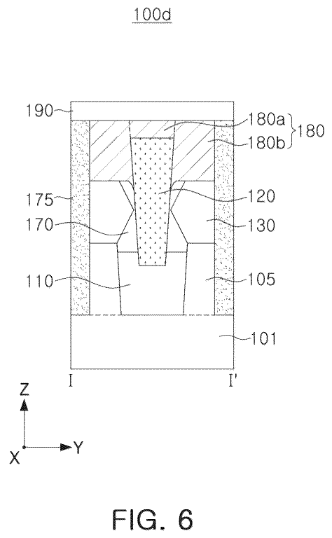

FIG. 6 is a cross-sectional view illustrating a semiconductor device according to example embodiments. FIG. 6 illustrates a cross-section corresponding to the cross-section cut taken along line I-I′ in FIG. 1.

Referring to FIG. 6, an inner side surface connecting a lower surface of a first portion 180a and a lower surface of a second portion 180b of the contact structure 180 may cover a side surface of the separation pattern 120, and the lowermost end of the inner side surface may be the lowermost end of the second portion 180b, and may be in contact with the separation pattern 120.

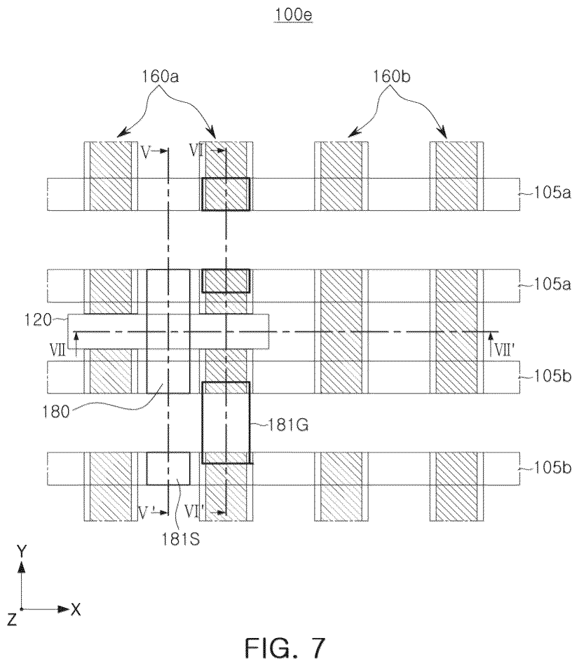

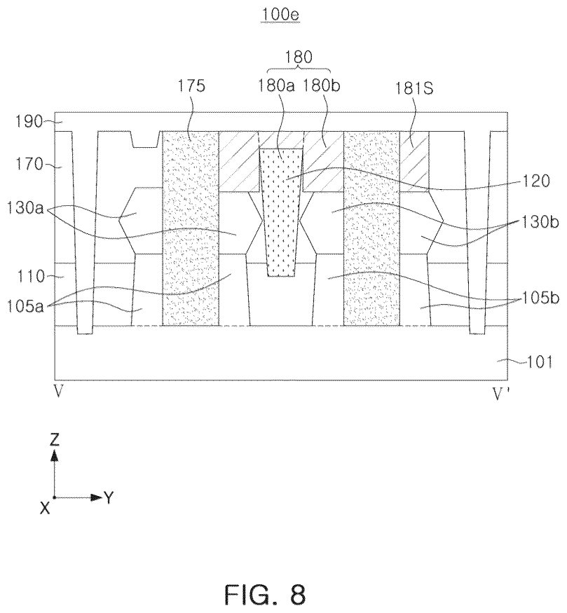

FIG. 7 is a cross-sectional view illustrating a semiconductor device according to example embodiments. FIGS. 8 to 10 are cross-sectional views illustrating semiconductor devices according to example embodiments. Only some components of the semiconductor device are illustrated in FIG. 7.

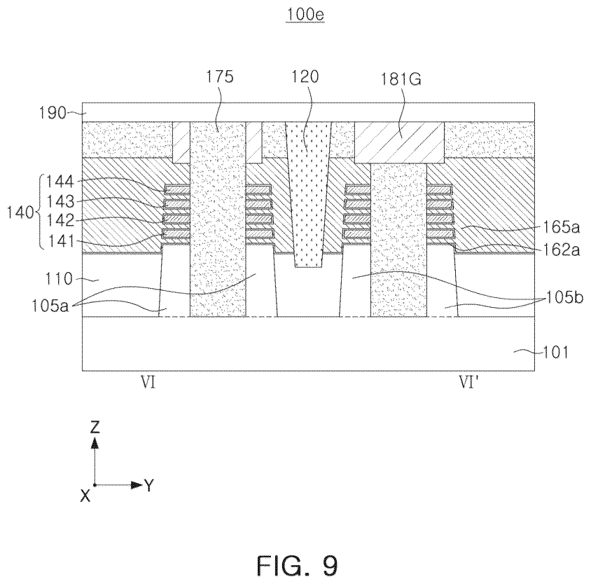

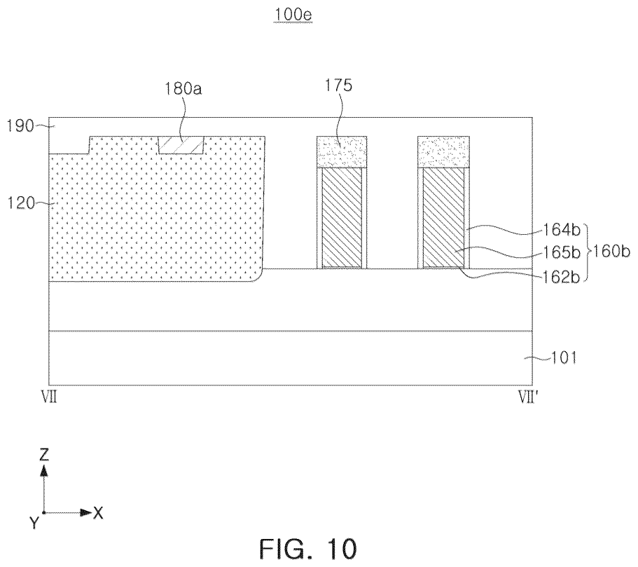

FIG. 8 illustrates a cross-section of the semiconductor device of FIG. 7 taken along line V-V′. FIG. 9 illustrates a cross-section of the semiconductor device of FIG. 7 taken along line VI-VI′. FIG. 10 illustrates a cross-section of the semiconductor device of FIG. 7 taken along line VII-VII′.

Referring to FIGS. 7 to 10, the semiconductor device 100e may include a first active region 105a, a second active region 105b, a first gate structure 160a, a second gate structure 160b, a separation pattern 120, an insulating region 175, and contact structures 180, 181S, and 181G. FIG. 7 illustrates only a portion of the contact structures 180, 181S, and 181G.

The first and second active regions 105a and 105b may extend in a first direction, for example, an X-direction, and may be disposed to be spaced apart in a second direction intersecting the first direction, for example, a Y-direction. The first active regions 105a may include an impurity having a first conductivity type, and the second active regions 105b may include an impurity having a second conductivity type different from the first conductivity type. When the first conductivity type is a P-type, the first conductivity-type impurities may include at least one of boron (B), aluminum (Al), gallium (Ga), and indium (In), and in this case, the second conductivity type is a N-type, the second conductivity-type impurities may include at least one of phosphorus (P), arsenic (As), and antimony (Sb).

The first source/drain regions 130a may be disposed on the first active regions 105a, and the second source/drain regions 130b may be disposed on the second active regions 105b.

The first and second gate structures 160a and 160b may be extend in a second direction intersecting the first and second active regions 105a and 105b on the first and second active regions 105a and 105b, for example, a Y-direction, and may be disposed to be spaced apart in a first direction, for example, an X-direction.

The first gate structures 160a may be separated by a recess region RS (see FIG. 12), and may be disposed to contact the separation pattern 120 filling the recess region (RS) see FIG. 12. Depending on an example embodiment, in a region, at least a portion of the first and second gate structures 160b may be separated by another recess region. In an embodiment, a recess region may have a shape extending in one direction or a hole shape. In an example embodiment, depending on the process, channel layers 140 disposed on both sides of the insulating region 175 may originally be configured to be integrated, but may be configured to be separated by the insulating region 175.

The separation pattern 120 may extend in a first direction, for example, an X-direction, to separate a plurality of first gate structures 160a. Depending on the embodiment, the separation pattern 120 may extend further in the X-direction to separate a portion of a plurality of second gate structures 160b. Depending on the embodiment, the number of gate structures separated by the separation pattern 120 may vary, and the separation pattern 120 may be present in plural. In a cross-section in the X-direction (see FIG. 10), the separation pattern 120 may include a portion having a concave upper surface in addition to the portion where the first portion 180a of the contact structure 180 is present, and the portion may be filled with the upper insulating layer 190.

The insulating region 175 may be disposed between adjacent first active regions 105a to be in contact with the first active regions 105a, or may be disposed between adjacent second active regions 105b to be in contact with the second active regions 105b. Each of the first active regions 105a and the first source/drain regions 130a may originally be formed integrally, but may be separated by an insulating region 175. Likewise, each of the second active regions 105b and the second source/drain regions 130b may originally be formed integrally, but may be separated by an insulating region 175. The insulating region 175 may be disposed to penetrate each of the first and second gate structures 160a and 160b. In an example embodiment, the insulating region 175 may not be present, and in this case, the insulating region 175 may include the same structure as the semiconductor device 100a described in FIGS. 3A and 3B.

The contact structures 180, 181S, and 180G may include a contact structure 180 that simultaneously contacts the separation pattern 120 and the first and second source/drain regions 130a and 130b, a (source/drain) contact structure 181S disposed on the source/drain regions 130a and 130b, and a (gate) contact structure 181G disposed on the gate structures 160a and 160b. Depending on the embodiment, the number, location of the contact structures 180, 181S, and 181G, and the like, may vary.

Depending on the process, the upper insulating layer 190 may include protrusions extending into the interior of the interlayer insulating layer 170. The upper insulating layer 190 may include a protrusion extending into the interior of the substrate 101 through the interlayer insulating layer 170 and the device isolation layer 110, and in a cross-section in the y direction (see FIG. 8), the protrusions may be disposed to be spaced apart with the contact structure 180 and the insulating region 175 interposed therebetween.

Contents not specifically described in the description related to FIGS. 7 to 10 may be understood as being the same as or similar to the configuration of the semiconductor device described in FIGS. 1 to 6.

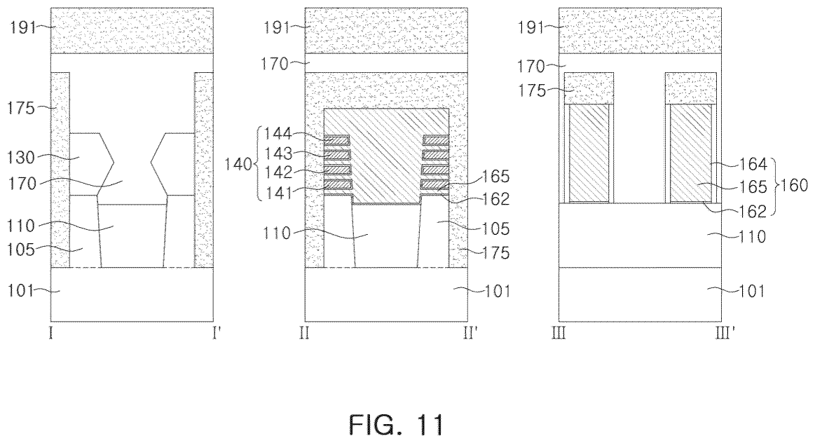

FIGS. 11 to 19 are diagrams illustrating a process sequence to explain a method of manufacturing a semiconductor device according to example embodiments. Respective cross-sectional views included in FIGS. 11 to 19 illustrate processes of the cross-sectional views of the semiconductor device shown in FIGS. 2A, 2B, and 2C from a left side.

Referring to FIG. 11, an active region 105, first to fourth channel regions 141, 142, 143, and 144, a gate structure 160, a device isolation layer 110, an interlayer insulating layer 170, and an insulating region 175 may be formed on the substrate 101. A preliminary protective layer 191 may be formed on the interlayer insulating layer 170.

The insulating region 175 may be formed by removing a portion of sacrificial layers, first to fourth channel layers 141, 142, 143, and 144, and an active region 105, stacked on the substrate 101, and filling the removed region. The insulating region 175 may be formed by removing a portion of the sacrificial layer, but embodiments of the disclosure are not limited thereto. In an example embodiment, the insulating region 175 may be formed by removing a portion of the gate electrode 165 after the sacrificial layer is removed and the gate electrode 165 is formed.

Referring to FIG. 12, a recess region RS penetrating the interlayer insulating layer 170 and the gate structure 160 and extending into the interior of the device isolation layer 110 may be formed. The gate structure 160 may be separated by the recess region RS. Referring to FIG. 1, the recess region RS may be in a form of a line extending in a first direction, for example, an X-direction. The recess region RS may be formed to be spaced apart from the substrate 101, the active region 105, and the source/drain region 130, but embodiments of the disclosure are not limited thereto. For example, in the process of manufacturing the semiconductor device 100b of FIG. 4, the recess region RS may be formed by removing a portion of the source/drain region 130 as well. In another example embodiment, in the process for forming the semiconductor device 100c of FIG. 5, the recess region RS may extend into the interior of the substrate 101.

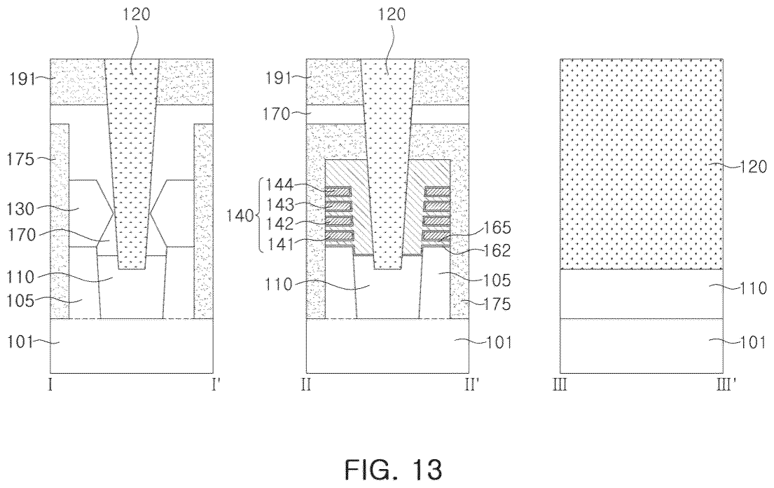

Referring to FIG. 13, a separation pattern 120 may be formed to fill the recess region RS. The separation pattern 120 may be formed of a material having etch selectivity different from that of the interlayer insulating layer 170. For example, when the interlayer insulating layer 170 includes silicon oxide, the separation pattern 120 may include silicon nitride.

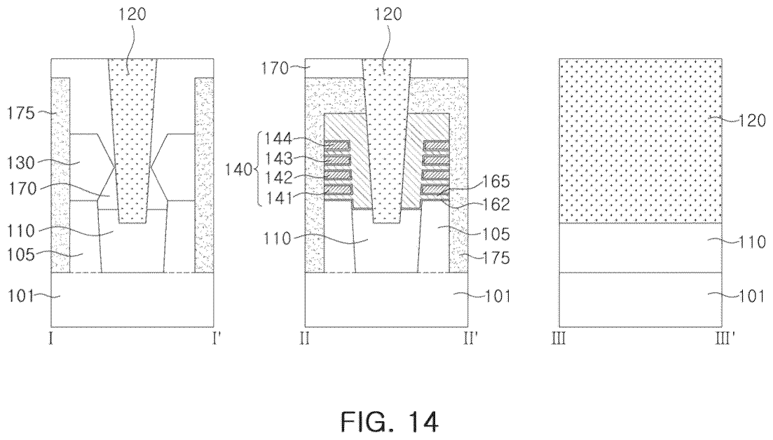

Referring to FIG. 14, a portion of the preliminary protective layer 191 and the separation pattern 120 located on a level higher than the upper surface of the interlayer insulating layer 170 may be removed. The processes followed by FIG. 14 may be processes for forming to have a structure including a first portion 180a in contact with the separation pattern 120 and a second portion 180b in contact with the source/drain region 130 as shown in FIG. 2A.

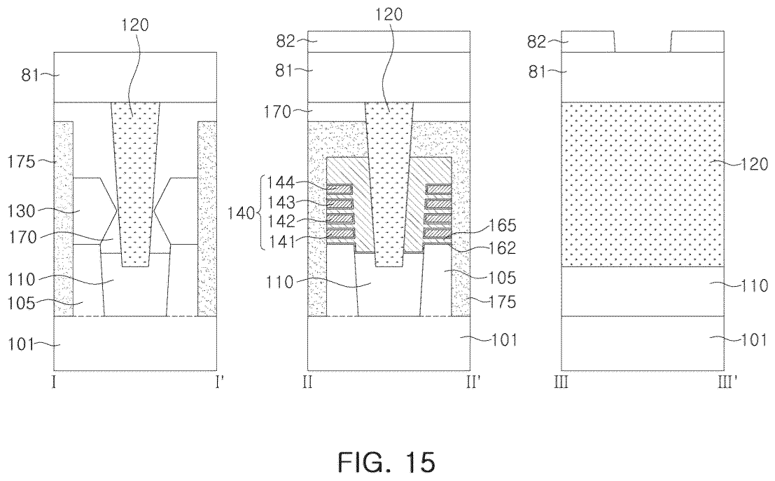

Referring to FIG. 15, masks 81 and 82 may be formed on an upper surface of the interlayer insulating layer 170 and an upper surface of the separation pattern 120. The upper mask 82 may include an opening for opening the portion to be etched by the separation pattern 120 to be formed by the first portion 180a of FIG. 2A.

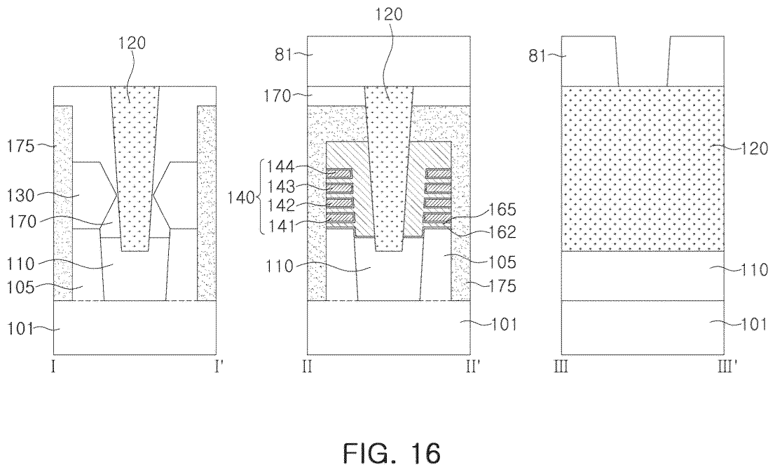

Referring to FIG. 16, an opening of the lower mask 81 may be formed using the lower mask 81 of the portion exposed by the opening of the upper mask 82 of FIG. 15, and the upper mask 82 may be removed.

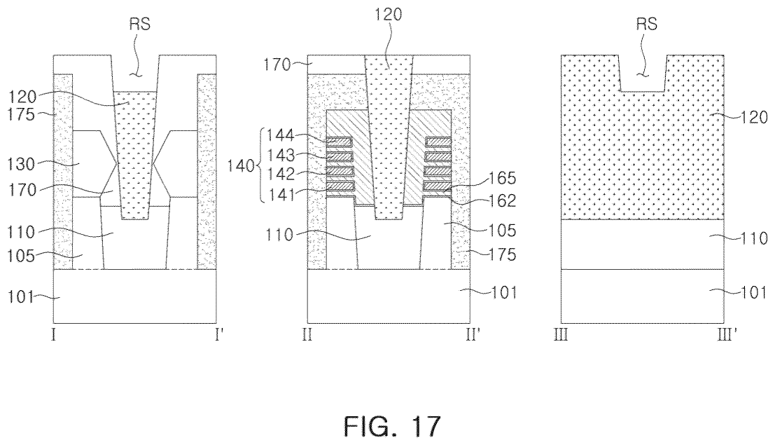

Referring to FIG. 17, a portion of an upper portion of the separation pattern 120 having etch selectivity different from that of the interlayer insulating layer 170 may be removed. The upper portion etched by the separation pattern 120 may be a portion exposed by the opening of the lower mask 81.

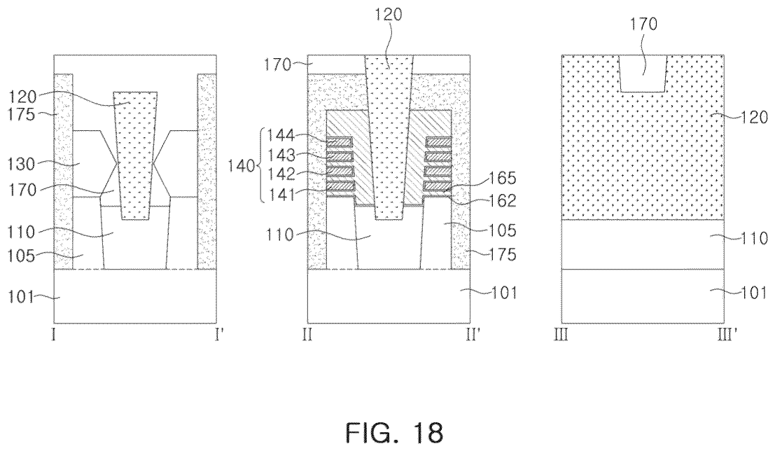

Referring to FIG. 18, a space where the separation pattern 120 was removed may be filled with a material having the same etch selectivity as the interlayer insulating layer 170. Even if the separation pattern 120 is formed in a form of a line extending in one direction by this process, the contact structure 180 can be formed by a self-aligned contact (SAC) process.

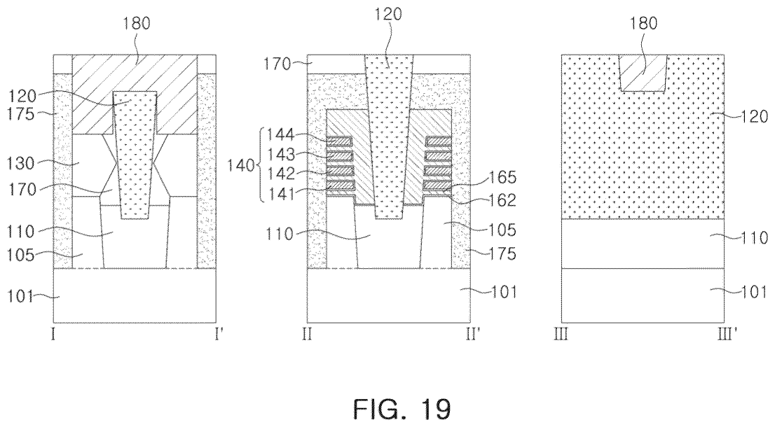

Referring to FIG. 19, a portion of the interlayer insulating layer 170 having etch selectivity different from that of the separation pattern 120 may be removed. In this case, a portion of the source/drain region 130 may be removed together. Thereafter, a contact structure 180 may be formed to fill the removed region. Referring to FIG. 2A together, the semiconductor device 100 of FIG. 2A can be manufactured by removing a portion of an upper portion of the contact structure 180.

By removing a portion of the separation pattern 120 in FIGS. 16 to 18, a first portion 180a may remain even if a portion of the upper portion of the contact structure 180 is removed. In this process, even if the separation pattern 120 is formed in a form of a line extending in one direction, and then the contact structure 180 may be formed by a self-aligned contact (SAC) process, so that a semiconductor device with improved degree of integration and reliability may be provided.

As set forth above, by optimizing a structure of a contact structure connected to a source/drain region, a semiconductor device with an improved degree of integration and electrical characteristics may be provided.

While example embodiments have been illustrated and described above, it will be apparent to those skilled in the art that modifications and variations could be made without departing from the scope of the disclosure as defined by the appended claims.

What is claimed is:

1. A semiconductor device comprising:
a substrate;
an active region extending in a first direction on the substrate;
a gate structure extending in a second direction on the active region and intersecting the active region;
a source/drain region on the active region on a side of the gate structure;
a separation pattern extending in the first direction and separating the gate structure; and
a contact structure on the separation pattern and crossing the separation pattern, the contact structure being electrically connected to the source/drain region,
wherein the contact structure comprises a first portion and a second portion,
wherein the first portion contacts the separation pattern,
wherein the second portion contacts the source/drain region,
wherein a lower surface of the second portion is at a level lower than a lower surface of the first portion, and
wherein a lowermost end of the contact structure is spaced apart from the separation pattern.

2. The semiconductor device of claim 1, wherein the separation pattern is spaced apart from the source/drain region.

3. The semiconductor device of claim 1, wherein a width of the separation pattern decreases toward the substrate.

4. The semiconductor device of claim 1, wherein the separation pattern extends in a third direction that is perpendicular to an upper surface of the substrate, and extends into the substrate.

5. The semiconductor device of claim 1, wherein an upper surface of the separation pattern comprises a first upper surface and a second upper surface,
wherein the first upper surface contacts the lower surface of the first portion, and
wherein the second upper surface is coplanar with an upper surface of the first portion.

6. The semiconductor device of claim 1, wherein the lower surface of the first portion is at a level higher than an upper end of the source/drain region.

7. The semiconductor device of claim 1, wherein the separation pattern is spaced apart from the substrate.

8. The semiconductor device of claim 1, further comprising:
a device isolation layer surrounding the active region in the substrate; and
an interlayer insulating layer covering a portion of the source/drain region on the device isolation layer,
wherein the separation pattern penetrates through the interlayer insulating layer and extends into the device isolation layer.

9. The semiconductor device of claim 8, wherein the interlayer insulating layer comprises silicon oxide, and
wherein the separation pattern comprises silicon nitride.

10. The semiconductor device of claim 1, further comprising an insulating region covering a side surface of the contact structure, a side surface of the source/drain region, and a side surface of the active region.

11. The semiconductor device of claim 1, wherein the separation pattern contacts the source/drain region.

12. The semiconductor device of claim 1, wherein a first thickness of the first portion of the contact structure is lower than a second thickness of the second portion of the contact structure.

13. The semiconductor device of claim 1, further comprising:
a plurality of channel layers spaced apart from each other in a third direction perpendicular to an upper surface of the substrate, on the active region, and surrounded by the gate structure,
wherein the plurality of channel layers comprise a first channel layer, a second channel layer, a third channel layer and a further channel layer that are sequentially disposed in the third direction, and
wherein the lower surface of the second portion at a level lower than a lower surface of the third channel layer.

14. A semiconductor device comprising:
a substrate;
an active region extending in a first direction on the substrate;
a gate structure extending in a second direction on the active region and intersecting the active region;
a source/drain region on the active region on at least one side of the gate structure; and
a contact structure electrically connected to the source/drain region,
wherein a lower surface of the contact structure comprises a first surface, a second surface at a level lower than the first surface, and an inner side surface connecting the first surface and the second surface,
wherein the first surface is spaced apart from the source/drain region,
wherein the second surface contacts the source/drain region, and
wherein the inner side surface is inclined so that a width of the contact structure becomes narrower toward the substrate.

15. The semiconductor device of claim 14, further comprising a separation pattern contacting the first surface and extending in the first direction,
wherein the gate structure is separated by the separation pattern.

16. The semiconductor device of claim 15, wherein at least a portion of the inner side surface is spaced apart from the separation pattern.

17. The semiconductor device of claim 15, wherein the second surface is spaced apart from the separation pattern in the second direction.

18. A semiconductor device comprising:
a substrate;
a plurality of active regions extending in a first direction on the substrate, and spaced apart from each other in a second direction intersecting the first direction;
a plurality of gate structures extending in the second direction on the plurality of active regions;
a plurality of source/drain regions on at least one side of the plurality of gate structures on the plurality of active regions;
a separation pattern extending in the first direction between the plurality of source/drain regions, and penetrating at least one gate structure among the plurality of gate structures to separate the at least one gate structure; and
a contact structure contacting the separation pattern on the separation pattern, and contacting a first source/drain region and a second source/drain region among the plurality of source/drain regions,
wherein a first lower surface of the contact structure contacting the separation pattern is at a level higher than a second lower surface of the contact structure contacting the first source/drain region and the second source/drain region,
wherein at least a portion of an inner side surface of the contact structure connecting the first lower surface and the second lower surface is spaced apart from the separation pattern, and
wherein the first source/drain region and the second source/drain region comprise impurities having different conductivity types.

19. The semiconductor device of claim 18, wherein the first source/drain region and the second source/drain region have a symmetrical shape with respect to the separation pattern.

20. The semiconductor device of claim 18, wherein the contact structure extends in the second direction, and
wherein a length of the contact structure extending in the second direction is greater than a minimum distance at which the plurality of active regions are spaced apart from each other.
